(19) United States
(12) Patent Application Publication
(10) Pub. No.: US 2016/0359121 A1
(43) Pub. Date: Dec. 8, 2016

(54) ORGANIC LIGHT-EMITTING DISPLAY DEVICE

(71) Applicant: Samsung Display Co., Ltd., Yongin-si (KR)

(72) Inventors: Naoyuki Ito, Yongin-si (KR); Seulong Kim, Yongin-si (KR); Younsun Kim, Yongin-si (KR); Dongwoo Shin, Yongin-si (KR); Sunghun Lee, Yongin-si (KR); Jungsub Lee, Yongin-si (KR); Changwoong Chu, Yongin-si (KR)

(21) Appl. No.: 14/986,420

(22) Filed: Dec. 31, 2015

(30) Foreign Application Priority Data
Jun. 3, 2015 (KR) 10-2015-0078667

(51) Int. Cl. H01L 51/00; H01L 27/32

(52) U.S. Cl. CPC H01L 51/0085; H01L 27/3213; H01L 27/3218; H01L 2251/558; H01L 51/5072

(57) ABSTRACT

An organic light-emitting display device includes a pixel including a first sub-pixel, a second sub-pixel, a third sub-pixel, and a fourth sub-pixel, where the first sub-pixel includes a first emission layer that emits a first color light, the second sub-pixel includes a second emission layer that emits a second color light, the third sub-pixel includes a third emission layer that emits a third color light, and the fourth sub-pixel includes a fourth emission layer that emits a fourth color light; the first color light, the second color light, the third color light, and the fourth color light are different from each other; at least one emission layer selected from the first emission layer, the second emission layer, the third emission layer, and the fourth emission layer includes an organometallic compound; and the organometallic compound includes iridium (Ir).

### CROSS-REFERENCE TO RELATED APPLICATION

This application claims priority to and the benefit of Korean Patent Application No. 10-2015-0078667, filed on Jun. 3, 2015, in the Korean Intellectual Property Office, the entire content of which is incorporated herein by reference.

### BACKGROUND

1. Field

One or more exemplary embodiments relate to an organic light-emitting display device.

2. Description of the Related Art

Organic light-emitting display devices have wide viewing angles, high contrast ratios, short response times, and low power consumption, and thus, application ranges thereof are expanded from personal portable devices, such as an MP3 player or a mobile phone, to a television (TV).

Organic light-emitting display devices are characterized as self-emitting devices, and are different from liquid crystal display devices in terms of not requiring an additional light source. Thus, organic light-emitting display devices may have reduced thickness and weight.

### SUMMARY

One or more exemplary embodiments include an organic light-emitting display device.

Additional aspects of embodiments will be set forth in part in the description which follows and, in part, will be apparent from the description, or may be learned by practice of the presented embodiments.

According to one or more exemplary embodiments, an organic light-emitting display device includes a pixel including a first sub-pixel, a second sub-pixel, a third sub-pixel, and a fourth sub-pixel,

where the first sub-pixel includes a first emission layer that emits a first color light, the second sub-pixel includes a second emission layer that emits a second color light, the third sub-pixel includes a third emission layer that emits a third color light, and the fourth sub-pixel includes a fourth emission layer that emits a fourth color light;

the first color light, the second color light, the third color light, and the fourth color light are different from each other;

at least one emission layer selected from the first emission layer, the second emission layer, the third emission layer, and the fourth emission layer includes an organometallic compound; and

the organometallic compound includes iridium (Ir).

### BRIEF DESCRIPTION OF THE DRAWINGS

These and/or other aspects will become apparent and more readily appreciated from the following description of the exemplary embodiments, taken in conjunction with the accompanying drawings in which:

FIG. 1A is a plan view schematically illustrating a structure of a pixel of an organic light-emitting display device according to an exemplary embodiment of the present disclosure, and FIG. 1B is a plan view schematically illustrating a structure of a pixel of an organic light-emitting display device according to an exemplary embodiment of the present disclosure;

FIG. 2 is a cross-sectional view schematically illustrating a structure of a pixel of an organic light-emitting display device according to an exemplary embodiment of the present disclosure;

FIG. 3 is a plan view schematically illustrating a structure of a pixel of an organic light-emitting display device according to an exemplary embodiment of the present disclosure;

FIG. 4 is a plan view schematically illustrating a structure of a pixel of an organic light-emitting display device according to an exemplary embodiment of the present disclosure; and

FIG. 5 is a diagram showing CIE chromaticity coordinates of a pixel including a red sub-pixel, a green sub-pixel, and a blue sub-pixel.

### DETAILED DESCRIPTION

Reference will now be made in more detail to exemplary embodiments, examples of which are illustrated in the accompanying drawings, wherein like reference numerals refer to like elements throughout, and thus repeated description thereof is not necessary. In this regard, the present exemplary embodiments may have different forms and should not be construed as being limited to the descriptions set forth herein. Accordingly, the exemplary embodiments are merely described below, by referring to the figures, to explain aspects of embodiments of the present description. Expressions such as “at least one of,” when preceding a list of elements, modify the entire list of elements and do not modify the individual elements of the list.

While terms such as “first,” “second,” etc., may be used to describe various components, such components should not be limited to the above terms. The above terms are used only to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “on,” “formed on,” or “connected to” another layer, region, or component, it can be directly or indirectly on, formed on, or connected to the other layer, region, or component. That is, for example, intervening layers, regions, or components may be present. In addition, it will also be understood that when an element or layer is referred to as being “between” two elements or layers, it can be the only element or layer between the two elements or layers, or one or more intervening elements or layers may also be present.

Sizes of components in the drawings may be exaggerated for convenience of explanation. In other words, since sizes and thicknesses of components in the drawings may be arbitrarily illustrated for convenience of explanation, the following embodiments are not limited thereto.

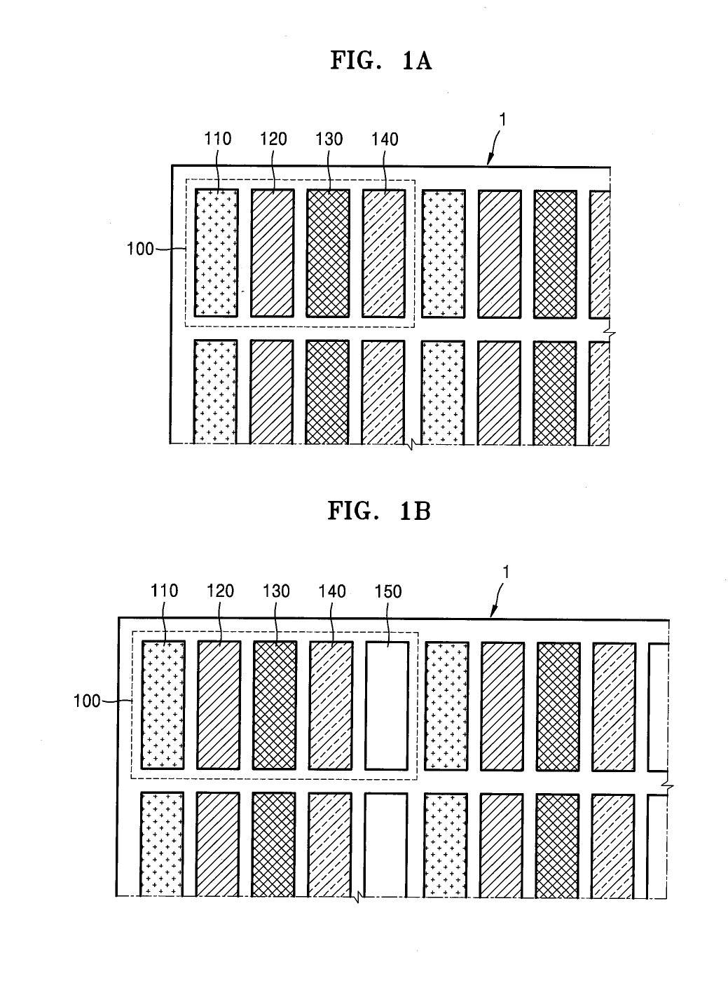

FIG. 1A is a view schematically illustrating a plane structure (e.g., a structure in a plane) of a pixel 100 of an organic light-emitting display device 1 according to an exemplary embodiment of the present disclosure. The organic light-emitting display device 1 may be prepared as a stripe type (e.g., a stripe kind of device).

The organic light-emitting display device 1 includes the pixel 100 including a first sub-pixel 110, a second sub-pixel 120, a third sub-pixel 130, and a fourth sub-pixel 140, wherein the first sub-pixel 110 includes a first emission layer that emits a first color light (e.g., a first color of light having a first color), the second sub-pixel 120 includes a second emission layer that emits a second color light (e.g., a second color of light having a second color), the third sub-pixel 130 includes a third emission layer that emits a third color light (e.g., a third color of light having a third color), and the fourth sub-pixel 140 includes a fourth emission layer that emits a fourth color light (e.g., a fourth color of light having a fourth color); the first color light, the second color light, the third color light, and the fourth color light are different from each other (e.g., the respective colors of the first color of light, the second color of light, the third color of light, and the fourth color of light may be different from each other); at least one emission layer selected from the first emission layer, the second emission layer, the third emission layer, and the fourth emission layer includes an organometallic compound; and the organometallic compound includes iridium (Ir). In some embodiments, the first sub-pixel, the second sub-pixel, the third sub-pixel, and the fourth sub-pixel are each a stripe type (e.g., in a stripe kind of device), a rectangular type (e.g., in a rectangular kind of device), or a pentile type (e.g., in a pentile kind of device).

For example, the organometallic compound may have a maximum emission wavelength in a range of about 540 nm to about 620 nm (e.g., the organometallic compound may emit light having a maximum wavelength of about 540 nm to about 620 nm), but the present disclosure is not limited thereto.

For example, the organometallic compound may be represented by Formula 1, but the present disclosure is not limited thereto:

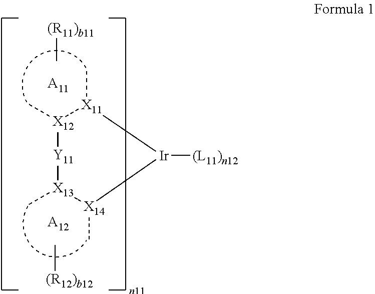

In Formula 1,

X₁₁ to X₁₄ may each be independently selected from a nitrogen atom and a carbon atom,

A₁₁ and A₁₂ may each be independently selected from a C₅-C₆₀ cyclic group and a C₁-C₆₀ heterocyclic group,

Y₁₁ may be selected from a single bond and a divalent linking group,

R₁₁ and R₁₂ may each be independently selected from a hydrogen, a deuterium, —F, —Cl, —Br, —I, a substituted or unsubstituted C₁-C₆₀ alkyl group, a substituted or unsubstituted C₆-C₆₀ aryl group, and a substituted or unsubstituted C₁-C₆₀ heteroaryl group,

R₁₁ and R₁₂ may be optionally fused to each other (e.g., combined together) to form a saturated or unsaturated ring,

b11 and b12 may be each independently selected from 1, 2, 3, and 4,

n11 may be selected from 1, 2, and 3,

L₁₁ may be selected from a monovalent organic ligand, a divalent organic ligand, a trivalent organic ligand, and a tetravalent organic ligand, and

n12 may be selected from 1, 2, 3, and 4.

The organometallic compound may be a phosphorescent dopant, but the organometallic compound is not limited thereto. Here, the phosphorescent dopant refers to a compound that emits phosphorescence (e.g., phosphorescent light). The organometallic compound may be a yellow phosphorescent dopant, but the present disclosure is not limited thereto.

In an exemplary embodiment, in Formula 1, X₁₁ may be a nitrogen atom and X₁₂ to X₁₄ may each be independently a carbon atom, but the present disclosure is not limited thereto.

In an exemplary embodiment, in Formula 1, A₁₁ and A₁₂ may each be independently selected from a benzene, a naphthalene, a fluorene, an indene, a pyrrole, a thiophene, a furan, an imidazole, a pyrazole, a thiazole, an isothiazole, an oxazole, an isoxazole, a triazole, a pyridine, a pyrazine, a pyrimidine, a pyridazine, a triazine, a quinoline, an isoquinoline, a quinoxaline, a quinazoline, an indole, a benzimidazole, a benzothiazole, a benzoxazole, a thienopyridine, a benzofuran, a benzothiophene, a dibenzofuran, and a dibenzothiophene, but the present disclosure is not limited thereto.

In an exemplary embodiment, in Formula 1, A₁₁ and A₁₂ may each be independently selected from a benzene, a naphthalene, a pyridine, a pyrazine, a quinoline, an isoquinoline, a benzothiazole, a benzoxazole, and a thienopyridine, but the present disclosure is not limited thereto.

In an exemplary embodiment, in Formula 1, Y₁₁ may be a single bond, but the present disclosure is not limited thereto.

In an exemplary embodiment, in Formula 1, R₁₁ and R₁₂ may each be independently selected from a hydrogen, a methyl group, an ethyl group, and a phenyl group, but the present disclosure is not limited thereto.

In an exemplary embodiment, in Formula 1, R₁₁ and R₁₂ may be connected to each other via Y₁₂,

Y₁₂ may be selected from a single bond, *—O—*′, *—S—*′, *—N(Z₁₁)—*′, *—[C(Z₁₁)(Z₁₂)]ₘ₁₁—*′, a group represented by Formula 10-1, and a group represented by Formula 10-2, but the present disclosure is not limited thereto:

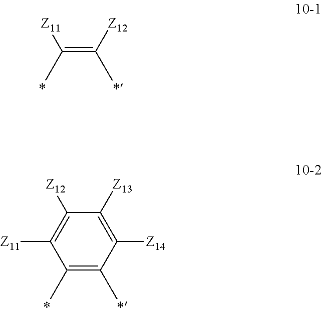

In some embodiments, in Formula 1, R₁₁ and R₁₂ may be connected to each other via a single bond, *—O—*′, *—S—*′, *—N(Z₁₁)—*′, *—[C(Z₁₁)(Z₁₂)]ₘ₁₁—*′, a group represented by Formula 10-1, or a group represented by Formula 10-2, but the present disclosure is not limited thereto. In Formulae 10-1 and 10-2, Z₁₁ to Z₁₄ may each be independently selected from a hydrogen, a deuterium, —F, —Cl, —Br, —I, a substituted or unsubstituted C₁-C₆₀ alkyl group, and a substituted or unsubstituted C₆-C₆₀ aryl group,

m11 may be selected from 1, 2, 3, and 4, and

* and *′ may each be independently a binding site to a neighboring atom.

In an exemplary embodiment, in Formulae 10-1 and 10-2, Z₁₁ to Z₁₄ may each be a hydrogen, but the present disclosure is not limited thereto.

In an exemplary embodiment, in Formula 1, n11 may be selected from 2 and 3, but the present disclosure is not limited thereto.

In an exemplary embodiment, in Formula 1, L₁₁ may be a monovalent organic ligand selected from a halogen ligand (e.g., I⁻, Br⁻, or Cl⁻), a carbon monoxide ligand, an isonitrile ligand, a cyano ligand, and a phosphorus ligand (e.g., phosphine, phosphate, or phosphite), but the present disclosure is not limited thereto.

In an exemplary embodiment, in Formula 1, L₁₁ may be a divalent organic ligand selected from a diketone ligand (e.g., acetylacetonate, 1,3-diphenyl-1,3-propanedionate, 2,2,6,6-tetramethyl-3,5-heptanedionate, or hexafluoroacetonate), a carboxylic acid ligand (e.g., picolinate, dimethyl-3-pyrazolecarboxylate, or benzoate), and a ligand represented by Formula 9, but the present disclosure is not limited thereto:

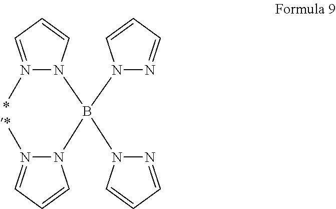

In Formula 9, * and *′ may each be independently a binding site to a neighboring atom.

In an exemplary embodiment, in Formula 1, L₁₁ may be a divalent organic ligand, but the present disclosure is not limited thereto. In an exemplary embodiment, in Formula 1, L₁₁ may be selected from acetylacetonate and the ligand of Formula 9, but the present disclosure is not limited thereto.

In an exemplary embodiment, in Formula 1, n12 may be 1, but the present disclosure is not limited thereto.

The organometallic compound of Formula 1 may be represented by one of Formulae 1-1 and 1-2, but the present disclosure is not limited thereto:

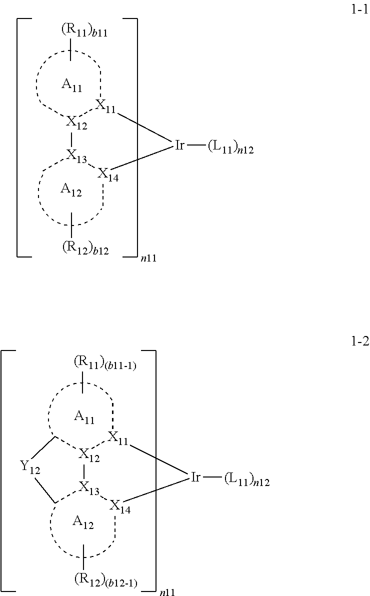

In Formulae 1-1 and 1-2,

descriptions of X₁₁ to X₁₄, A₁₁, A₁₂, Z₁₁, Z₁₂, R₁₁, R₁₂, b11, b12, n11, L₁₁, and n12 are defined the same as those provided in connection with Formula 1, and

Y₁₂ may be selected from a single bond, *—O—*′, *—S—*′, *—N(Z₁₁)—*′, *—[C(Z₁₁)(Z₁₂)]ₘ₁₁—*′, the group of 10-1, and the group of Formula 10-2:

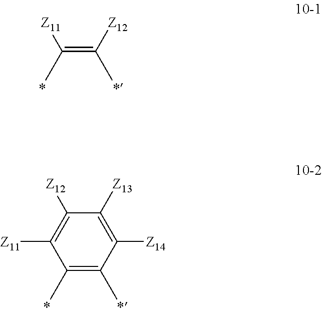

In Formulae 10-1 and 10-2, Z₁₁ to Z₁₄ may each be independently selected from a hydrogen, a deuterium, —F, —Cl, —Br, —I, a substituted or unsubstituted C₁-C₆₀ alkyl group, and a substituted or unsubstituted C₆-C₆₀ aryl group,

m11 may be selected from 1, 2, 3, and 4, and

* and *′ may each be independently a binding site to a neighboring atom.

The organometallic compound of Formula 1 may be selected from Compounds 1 to 12 below, but the present disclosure is not limited thereto:

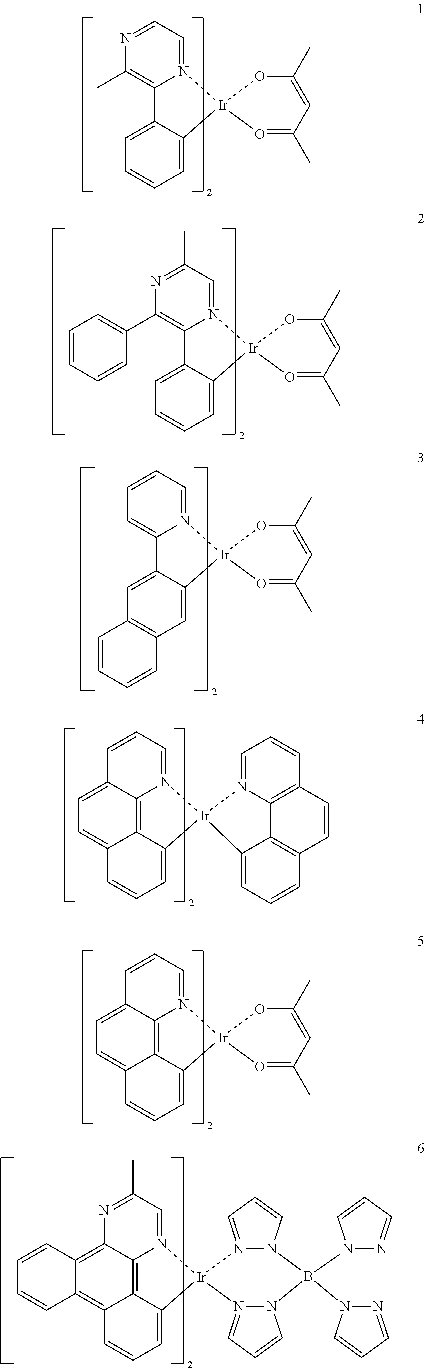

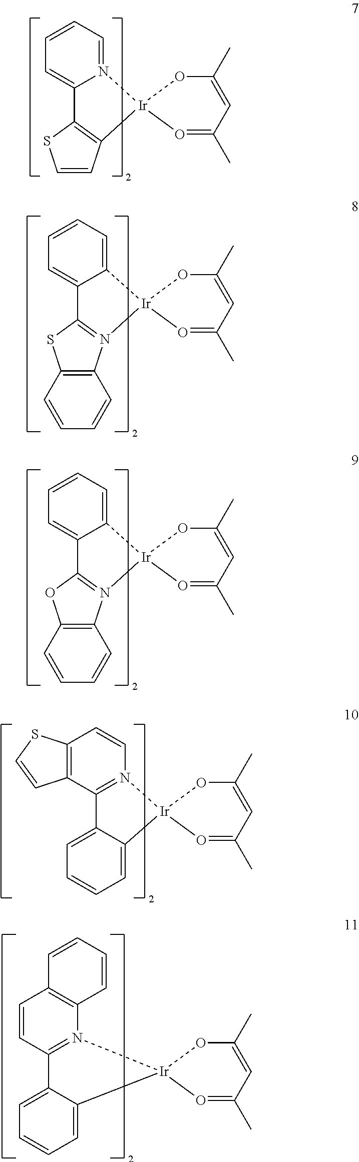

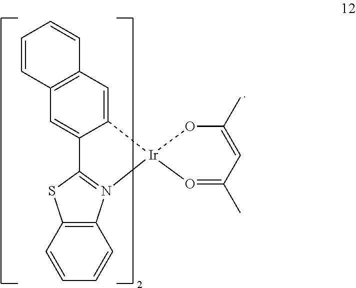

In an exemplary embodiment, the first color light, the second color light, the third color light, and the fourth color light of the pixel 100 may be combined with each other to emit white light.

In an exemplary embodiment, only one emission layer selected from the first to fourth emission layers may include the organometallic compound. For example, in some embodiments, only the fourth emission layer may include the organometallic compound, but the present disclosure is not limited thereto.

In an exemplary embodiment, the first color light may be red color light (e.g., the first color of light may be red), the second color light may be green color light (e.g., the second color of light may be green), the third color light may be blue color light (e.g., the third color of light may be blue), and the fourth color light may be yellow color light (e.g., the fourth color of light may be yellow), but the present disclosure is not limited thereto. In an exemplary embodiment, the fourth color light (e.g., the yellow color light) may have a maximum wavelength in a range of about 540 nm to about 620 nm, but the present disclosure is not limited thereto. In an exemplary embodiment, the first color light (e.g., the red color light) may have a maximum wavelength in a range of about 580 nm to about 700 nm, but the present disclosure is not limited thereto. In an exemplary embodiment, the second color light (e.g., the green color light) may have a maximum wavelength in a range of about 500 nm to about 600 nm, but the present disclosure is not limited thereto. In an exemplary embodiment, the third color light (e.g., the blue color light) may have a maximum wavelength in a range of about 400 nm to about 500 nm, but the present disclosure is not limited thereto.

In an exemplary embodiment, at least one of external quantum efficiencies of the first sub-pixel 110, the second sub-pixel 120, the third sub-pixel 130, and the fourth sub-pixel 140 may be greater than 20% to 100% (e.g., at least one selected from the first sub-pixel 110, the second sub-pixel 120, the third sub-pixel 130, and the fourth sub-pixel 140 may have an external quantum efficiency of greater than 20% to 100%), but the present disclosure is not limited thereto.

In an exemplary embodiment, areas of the first sub-pixel 110, the second sub-pixel 120, the third sub-pixel 130, and the fourth sub-pixel 140 may be identical (e.g., substantially identical) to or different from each other, but the present disclosure is not limited thereto.

In FIG. 1A, a structure of the pixel 100 in which the first sub-pixel 110, the second sub-pixel 120, the third sub-pixel 130, and the fourth sub-pixel 140 are sequentially disposed in the stated order is illustrated, but the structure is not limited thereto. For example, the pixel 100 may have a structure in which the first sub-pixel 110 and the fourth sub-pixel 140 are disposed adjacent to each other, a structure in which the second sub-pixel 120 and the fourth sub-pixel 140 are disposed adjacent to each other, or a structure in which the third sub-pixel 130 and the fourth sub-pixel 140 are disposed adjacent to each other.

FIG. 1B is a plan view schematically illustrating a structure of the pixel 100 of the organic light-emitting display device 1 according to an exemplary embodiment. The organic light-emitting display device 1 may be prepared as a stripe type (e.g., a stripe kind of device). For example, the organic light-emitting display device of FIG. 1B may further include a sub-pixel in addition to the organic light-emitting display device of FIG. 1A.

In an exemplary embodiment, the pixel 100 may further include a fifth sub-pixel 150. The fifth sub-pixel 150 may include a fifth emission layer that emits a fifth color light (e.g., a fifth color of light having a fifth color), wherein the fifth color light may be identical (e.g., substantially identical) to or different from one selected from the the first color light, the second color light, the third color light, and the fourth color light (e.g., the color of the fifth color of light may be identical (e.g., substantially identical) to or different from a color selected from the respective colors of the first color of light, the second color of light, the third color of light, and the fourth color of light), but the present disclosure is not limited thereto.

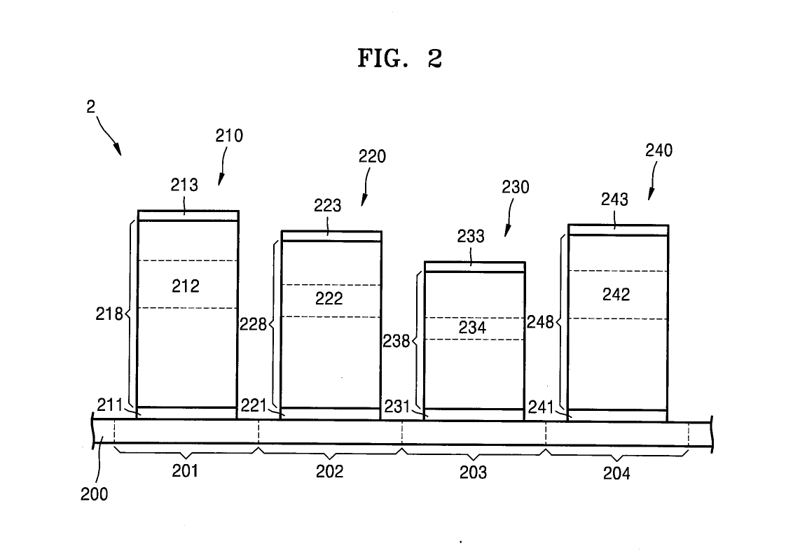

FIG. 2 is a cross-sectional view schematically illustrating a structure of a pixel of an organic light-emitting display device 2 according to an exemplary embodiment.

The organic light-emitting display device 2 may include a first sub-pixel 210, a second sub-pixel 220, a third sub-pixel 230, and a fourth sub-pixel 240.

The organic light-emitting display device 2 may include a substrate 200 including a first sub-pixel region 201, a second sub-pixel region 202, a third sub-pixel region 203, and a fourth sub-pixel region 204.

The substrate 200 may be a glass substrate or a transparent plastic substrate, each having excellent mechanical strength, thermal stability, transparency, surface smoothness, ease of handling, and water repellency.

The first sub-pixel 210 may be disposed on the first sub-pixel region 201, the second sub-pixel 220 may be disposed on the second sub-pixel region 202, the third sub-pixel 230 may be disposed on the third sub-pixel region 203, and the fourth sub-pixel 240 may be disposed on the fourth sub-pixel region 204.

The first sub-pixel 210, the second sub-pixel 220, the third sub-pixel 230, and the fourth sub-pixel 240 may include first electrodes 211, 221, 231, and 241, respectively, and second electrodes 213, 223, 233, and 243, respectively, wherein the second electrodes 213, 223, 233, and 243 face opposite to the first electrodes 211, 221, 231, and 241, respectively.

The first electrodes 211, 221, 231, and 241 may be formed by, for example, depositing or sputtering a respective material for forming the first electrodes 211, 221, 231, and 241 on the substrate 200. When the first electrodes 211, 221, 231, and 241 are anodes, the material for forming the first electrodes 211, 221, 231, and 241 may be selected from materials having a high work function to facilitate hole injection. The first electrodes 211, 221, 231, and 241 may be reflective electrodes, semi-transmissive electrodes, or transmissive electrodes. The material for forming the first electrodes 211, 221, 231, and 241 may be indium tin oxide (ITO), indium zinc oxide (IZO), tin oxide (SnO₂), or zinc oxide (ZnO), each having transparency and excellent conductivity. Alternatively, or additionally, to form the first electrodes 211, 221, 231, and 241 as semi-transmissive electrodes or reflective electrodes, the material for forming the first electrodes 211, 221, 231, and 241 may be at least one selected from magnesium (Mg), aluminum (Al), aluminum-lithium (Al—Li), calcium (Ca), magnesium-indium (Mg—In), and magnesium-silver (Mg—Ag).

The first electrodes 211, 221, 231, and 241 may have a single-layer structure or a multi-layer structure including a plurality of layers. For example, the first electrodes 211, 221, 231, and 241 may have a triple-layered structure of ITO/Ag/ITO, but the structure is not limited thereto.

The second electrodes 213, 223, 233, and 243 may be cathodes, which are electron injection electrodes. Here, a material for forming the second electrodes 213, 223, 233, and 243 may be metals having a low work function, alloys, electrically conductive compounds, or mixtures thereof. Examples of the second electrodes 213, 223, 233, and 243 include Li, Mg, Al, Al—Li, Ca, Mg—In, and Mg—Ag. Alternatively, or additionally, the material for forming second electrodes 213, 223, 233, and 243 may be ITO or IZO. The second electrodes 213, 223, 233, and 243 may be reflective electrodes, semi-transmissive electrodes, or transmissive electrodes.

Organic layers 218, 228, 238, and 248 may be disposed between the first electrodes 211, 221, 231, and 241 and the second electrodes 213, 223, 233, and 243.

The first sub-pixel 210 may include a first emission layer 212 that emits a first color light (e.g., a first color of light having a first color), the second sub-pixel 220 may include a second emission layer 222 that emits a second color light (e.g., a second color of light having a second color), the third sub-pixel 230 may include a third emission layer 232 that emits a third color light (e.g., a third color of light having a third color), and the fourth sub-pixel 240 may include a fourth emission layer 242 that emits a fourth color light (e.g., a fourth color of light having a fourth color).

The organic layers 218, 228, 238, and 248 may further include hole transport regions respectively between respective ones of the first electrodes 211, 221, 231, and 241 and the first to fourth emission layers 212, 222, 232, and 242. The organic layers 218, 228, 238, and 248 may also further include electron transport regions respectively between respective ones the first to fourth emission layers 212, 222, 232, and 242 to the second electrodes 213, 223, 233, and 243.

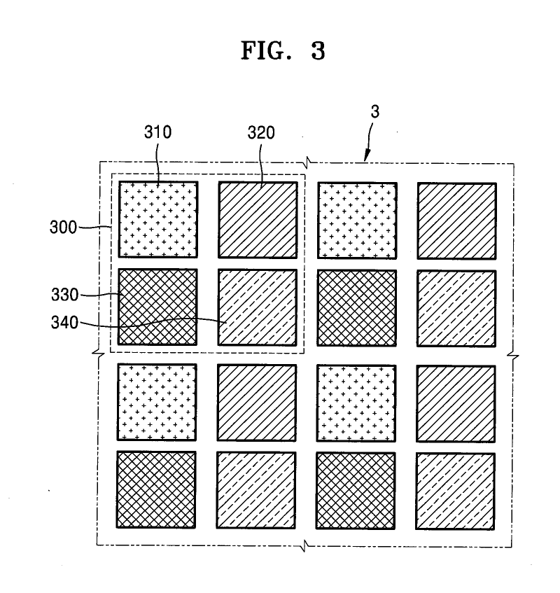

FIG. 3 is a plan view schematically illustrating a structure of a pixel 300 of an organic light-emitting display device 3 according to an exemplary embodiment. The organic light-emitting display device 3 may be prepared as a rectangular (e.g., square) type (e.g., a rectangular or square kind of device).

The organic light-emitting display device 3 includes the pixel 300 including a first sub-pixel 310, a second sub-pixel 320, a third sub-pixel 330, and a fourth sub-pixel 340, wherein the first sub-pixel 310 includes a first emission layer that emits a first color light (e.g., a first color of light having a first color), the second sub-pixel 320 includes a second emission layer that emits a second color light (e.g., a second color of light having a second color), the third sub-pixel 330 includes a third emission layer that emits a third color light (e.g., a third color of light having a third color), and the fourth sub-pixel 340 includes a fourth emission layer that emits a fourth color light (e.g., a fourth color of light having a fourth color); the first color light, the second color light, the third color light, and the fourth color light may be different from each other (e.g., the respective colors of the first color of light, the second color of light, the third color of light, and the fourth color of light may be different from each other); and at least one emission layer of the first to fourth emission layers may include the organometallic compound of Formula 1.

In an exemplary embodiment, the first color light, the second color light, the third color light, and the fourth color light of the pixel 300 may be combined with each other to emit white light.

In an exemplary embodiment, only one emission layer selected from the first to fourth emission layers the organometallic compound. For example, only the fourth emission layer may include the organometallic compound, but the present disclosure is not limited thereto.

In an exemplary embodiment, the first color light may be red color light (e.g., the first color of light may be red), the second color light may be green color light (e.g., the second color of light may be green), the third color light may be blue color light (e.g., the third color of light may be blue), and the fourth color light may be yellow color light (e.g., the fourth color of light may be yellow), but the present disclosure is not limited thereto. In an exemplary embodiment, the fourth color light (e.g., the yellow color light) may have a maximum wavelength in a range of about 540 nm to about 620 nm, but the present disclosure is not limited thereto. In an exemplary embodiment, the first color light (e.g., the red color light) may have a maximum wavelength in a range of about 580 nm to about 700 nm, but the present disclosure is not limited thereto. In an exemplary embodiment, the second color light (e.g., the green color light) may have a maximum wavelength in a range of about 500 nm to about 600 nm, but the present disclosure is not limited thereto. In an exemplary embodiment, the third color light (e.g., the blue color light) may have a maximum wavelength in a range of about 400 nm to about 500 nm, but the present disclosure is not limited thereto.

In an exemplary embodiment, at least one of external quantum efficiencies of the first sub-pixel 310, the second sub-pixel 320, the third sub-pixel 330, and the fourth sub-pixel 340 may be greater than 20% to 100% (e.g., at least one selected from the first sub-pixel 310, the second sub-pixel 320, the third sub-pixel 330, and the fourth sub-pixel 340 may have an external quantum efficiency of greater than 20% to 100%), but the present disclosure is not limited thereto.

In an exemplary embodiment, areas of the first sub-pixel 310, the second sub-pixel 320, the third sub-pixel 330, and the fourth sub-pixel 340 may be identical (e.g., substantially identical) to or different from each other, but the present disclosure is not limited thereto.

In FIG. 3, a structure of the pixel 300 in which the first sub-pixel 310 is disposed adjacent to the second sub-pixel 320 and the third sub-pixel 330, the second sub-pixel 320 is disposed adjacent to the first sub-pixel 310 and the fourth sub-pixel 340, the third sub-pixel 330 is disposed adjacent to the first sub-pixel 310 and the fourth sub-pixel 340, and the fourth sub-pixel 340 is disposed adjacent to the second sub-pixel 320 and the third sub-pixel 330 is illustrated, but the structure is not limited thereto. For example, the pixel 300 may have a structure in which the first sub-pixel 310 and the fourth sub-pixel 340 are disposed adjacent to each other.

In an exemplary embodiment, the pixel 300 may further include a fifth sub-pixel. The fifth sub-pixel may include a fifth emission layer that emits a fifth color light (e.g., a fifth color of light having a fifth color), wherein the fifth color light may be identical (e.g., substantially identical) to or different from one selected from the first color light, the second color light, the third color light, and the fourth color light (e.g., the color of the fifth color of light may be identical (e.g., substantially identical) to or different from a color selected from the respective colors of the first color of light, the second color of light, the third color of light, and the fourth color of light), but the present disclosure is not limited thereto.

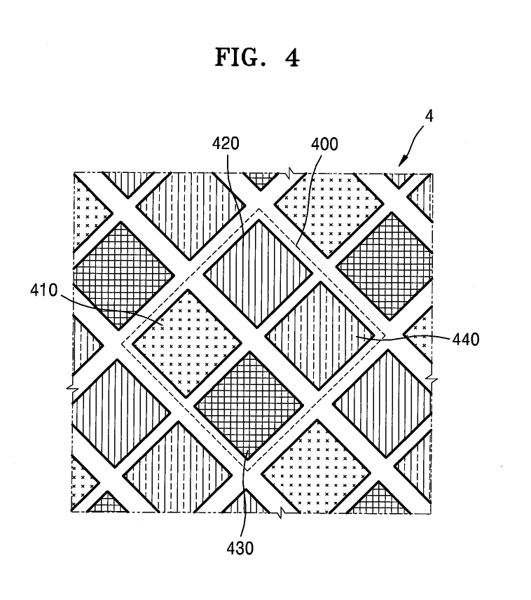

FIG. 4 is a plan view schematically illustrating a structure of a pixel 400 of an organic light-emitting display device 4 according to an exemplary embodiment. The organic light-emitting display device 4 may be prepared as a pentile type (e.g., a pentile kind of device where the pixels are arranged in a pentile matrix).

The organic light-emitting display device 4 includes the pixel 400 including a first sub-pixel 410, a second sub-pixel 420, a third sub-pixel 430, and a fourth sub-pixel 440, wherein the first sub-pixel 410 includes a first emission layer that emits a first color light (e.g., a first color of light having a first color), the second sub-pixel 420 includes a second emission layer that emits a second color light (e.g., a second color of light having a second color), the third sub-pixel 430 includes a third emission layer that emits a third color light (e.g., a third color of light having a third color), the fourth sub-pixel 440 includes a fourth emission layer that emits a fourth color light (e.g., a fourth color of light having a fourth color); the first color light, the second color light, the third color light, and the fourth color light may be different from each other; and at least one emission layer selected from the first to fourth emission layers may include the organometallic compound of Formula 1.

In an exemplary embodiment, the first color light, the second color light, the third color light, and the fourth color light of the pixel 400 may be combined with each other to emit (e.g., form) white light.

In an exemplary embodiment, only one emission layer selected from the first to fourth emission layers includes the organometallic compound. For example, in some embodiments, only the fourth emission layer may include the organometallic compound, but the present disclosure is not limited thereto.

In an exemplary embodiment, the first color light may be red color light (e.g., the first color of light may be red), the second color light may be green color light (e.g., the second color of light may be green), the third color light may be blue color light (e.g., the third color of light may be blue), and the fourth color light may be yellow color light (e.g., the fourth color of light may be yellow), but the present disclosure is not limited thereto. In an exemplary embodiment, the fourth color light (e.g., the yellow color light) may have a maximum wavelength in a range of about 540 nm to about 620 nm, but the present disclosure is not limited thereto. In an exemplary embodiment, the first color light (e.g., the red color light) may have a maximum wavelength in a range of about 580 nm to about 700 nm, but the present disclosure is not limited thereto. In an exemplary embodiment, the second color light (e.g., the green color light) may have a maximum wavelength in a range of about 500 nm to about 600 nm, but the present disclosure is not limited thereto. In an exemplary embodiment, the third color light (e.g., the blue color light) may have a maximum wavelength in a range of about 400 nm to about 500 nm, but the present disclosure is not limited thereto.

In an exemplary embodiment, at least one of external quantum efficiencies of the first sub-pixel 410, the second sub-pixel 420, the third sub-pixel 430, and the fourth sub-pixel 440 may be greater than 20% to 100% (e.g., at least one selected from the first sub-pixel 410, the second sub-pixel 420, the third sub-pixel 430, and the fourth sub-pixel 440 may have an external quantum efficiency of greater than 20% to 100%), but the present disclosure is not limited thereto.

In an exemplary embodiment, areas of the first sub-pixel 410, the second sub-pixel 420, the third sub-pixel 430, and the fourth sub-pixel 440 may be identical (e.g., substantially identical) to or different from each other, but the present disclosure is not limited thereto.

In FIG. 4, a structure of the pixel 400 in which the first sub-pixel 410 is disposed adjacent to the second sub-pixel 420 and the third sub-pixel 430, the second sub-pixel 420 is disposed adjacent to the first sub-pixel 410 and the fourth sub-pixel 440, the third sub-pixel 430 is disposed adjacent to the first sub-pixel 410 and the fourth sub-pixel 440, and the fourth sub-pixel 440 is disposed adjacent to the second sub-pixel 420 and the third sub-pixel 430 is illustrated, but the structure is not limited thereto. For example, the pixel 400 may have a structure in which the first sub-pixel 410 and the fourth sub-pixel 440 are disposed adjacent to each other.

In an exemplary embodiment, the pixel 400 may further include a fifth sub-pixel. The fifth sub-pixel may include a fifth emission layer that emits a fifth color light (e.g., a fifth color of light having a fifth color), wherein the fifth color light may be identical (e.g., substantially identical) to or different from one of the the first color light, the second color light, the third color light, and the fourth color light (e.g., the color of the fifth color of light may be identical (e.g., substantially identical) to or different from a color selected from the respective colors of the first color of light, the second color of light, the third color of light, and the fourth color of light), but the present disclosure is not limited thereto.

Hereinabove, the organic light-emitting display device has been described with reference to FIGS. 1 to 4, but the present disclosure is not limited thereto.

The first color light, the second color light, the third color light, and the fourth color light may form a convex polygon including white color in CIE chromaticity coordinates, wherein two color lights selected from the first color light, the second color light, the third color light, and the fourth color light may be complementary to each other.

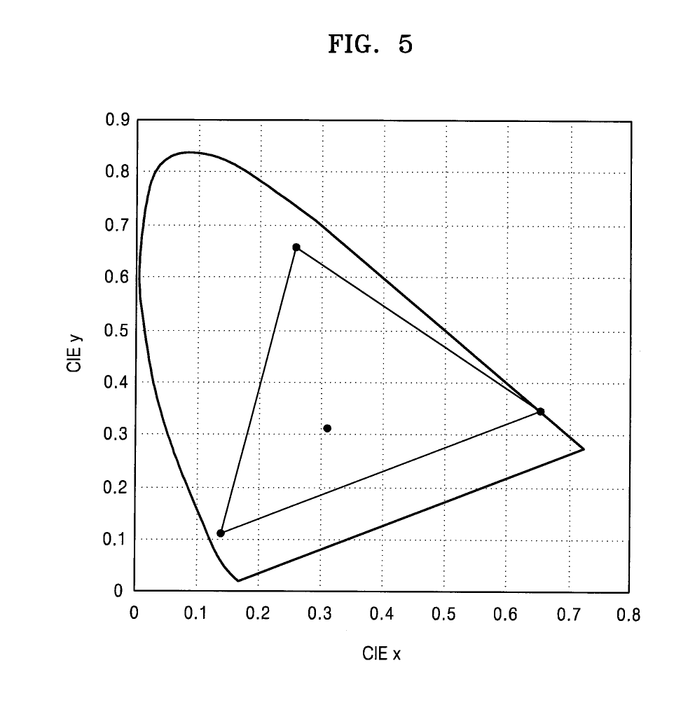

A standard color gamut that represents the color reproduction ranges may be, for example, the National Television System Committee (NTSC) standard. A method of defining a color gamut that is 100% of the NTSC color gamut is described by referring to FIG. 5. FIG. 5 shows CIE chromaticity coordinates for each of red, green, and blue, wherein red has CIE chromaticity coordinates of x=0.67 and y=0.33, green has CIE chromaticity coordinates of x=0.21 and y=0.71, blue has CIE chromaticity coordinates of x=0.14 and y=0.08, and white has CIE chromaticity coordinates of x=0.31 and y=0.316. In FIG. 5, an area of a triangle produced by given CIE chromaticity coordinates of red, green, and blue is defined as 100% of the NTSC color gamut area. As described herein, widening the color gamut of the organic light-emitting display device means that the color gamut of the organic light-emitting display device approaches close to 100% of the NTSC color gamut.

Thus, to widen the color gamut of the organic light-emitting display device, the organic light-emitting display device may further include, in addition to a red sub-pixel, a green sub-pixel, and a blue sub-pixel, a sub-pixel that emits a color outside the gamut defined by red, green, and blue.

Here, the sub-pixel that emits a color outside the gamut defined by red, green, and blue may include an iridium (Ir)-including organometallic compound, and accordingly, the organic light-emitting display device may have high color purity, low power consumption, and long lifespan characteristics.

In addition, since various types or kinds of the Ir-including organometallic compound have been developed, in manufacturing the organic light-emitting display device, one of ordinary skill in the art may have advantages in selecting materials. For example, any suitable Ir-including organometallic compound available in the art may be selected for the organic light-emitting display device, and the Ir-including organometallic compound may be selected based on performance characteristics of the resultant organic light-emitting display device.

As used herein, the term “C₁-C₆₀ alkyl group” refers to a linear or branched aliphatic monovalent hydrocarbon group having 1 to 60 carbon atoms, and examples of the C₁-C₆₀ alkyl group include a methyl group, an ethyl group, an n-propyl group, an iso-propyl group, an n-butyl group, an iso-butyl group, a sec-butyl group, a tert-butyl group, a pentyl group, an iso-amyl group, and a hexyl group. As used herein, the term “C₁-C₆₀ alkylene group” refers to a divalent group having substantially the same structure as the C₁-C₆₀ alkyl group, except that the C₁-C₆₀ alkylene group is divalent instead of monovalent.

As used herein, the term “C₆-C₆₀ aryl group” refers to a monovalent group including a carbocyclic aromatic system having 6 to 60 carbon atoms, and the term “C₆-C₆₀ arylene group,” as used herein, refers to a divalent group including a carbodyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group include two or more rings, the respective rings may be fused to each other.

As used herein, the term “C₁-C₆₀ heteroaryl group” refers to a monovalent group having a carbocyclic aromatic system including at least one hetero atom selected from N, O, P, and S as a ring-forming atom and 1 to 60 carbon atoms. As used herein, the term “C₁-C₆₀ heteroarylene group” refers to a divalent group having a carbocyclic aromatic system including at least one hetero atom selected from N, O, P, and S as a ring-forming atom and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group include two or more rings, the respective rings may be fused to each other.

At least one substituent of the substituted C₁-C₆₀ alkyl group, the substituted C₆-C₆₀ aryl group, and the substituted C₁-C₆₀ heteroaryl group may be selected from:

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocyclo alkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), and —B(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇),

wherein Q₁₁ to Q₁₇, Q₂₁ to Q₂₇, and Q₃₁ to Q₃₇ may each be independently selected from:

a C₁-C₆₀ alkyl group, a C₆-C₆₀ aryl group, a C₁-C₆₀ heteroaryl group, a monovalent non-aromatic condensed polycyclic group, and a monovalent non-aromatic condensed heteropolycyclic group; and

a C₆-C₆₀ aryl group, a C₁-C₆₀ heteroaryl group, a monovalent non-aromatic condensed polycyclic group, and a monovalent non-aromatic condensed heteropolycyclic group, each substituted with a C₆-C₆₀ aryl group.

For example, at least one substituent of the substituted C₁-C₆₀ alkyl group, the substituted C₆-C₆₀ aryl group, and the substituted C₁-C₆₀ heteroaryl group may be selected from:

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₃₀ alkyl group, a C₂-C₃₀ alkenyl group, a C₂-C₃₀ alkynyl group, and a C₁-C₃₀ alkoxy group;

a C₁-C₃₀ alkyl group, a C₂-C₃₀ alkenyl group, a C₂-C₃₀ alkynyl group, and a C₁-C₃₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocyclo alkyl group, a C₃-C₁₀ cycloalkenyl group, a C₁-C₁₀ heterocycloalkenyl group, a C₆-C₃₀ aryl group, a C₆-C₃₀ aryloxy group, a C₆-C₃₀ arylthio group, a C₁-C₃₀ heteroaryl group, a monovalent non-aromatic condensed polycyclic group, a monovalent non-aromatic condensed heteropolycyclic group, —N(C)₁₁)(Q₁₂), —Si(Q₁₃)(Q₁₄)(Q₁₅), and —B(Q₁₆)(Q₁₇);

a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, and an imidazopyridinyl group, each substituted with at least one selected from a cyclopentyl group, a cyclohexyl group, a cycloheptyl group, a cyclooctyl group, a cyclopentenyl group, a cyclohepcenyl group, a cycloheptenyl group, a phenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, and a quinazolinyl group;

a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, and an imidazopyridinyl group, each substituted with at least one selected from a cyclopentyl group, a cyclohexyl group, a cycloheptyl group, a cyclooctyl group, a cyclopentenyl group, a cyclohexenyl group, a cycloheptenyl group, a phenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, and a quinazolinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₃₀ alkyl group, C₂-C₃₀ alkenyl group, a C₂-C₃₀ alkynyl group, a C₁-C₃₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₃₀ aryl group, a C₆-C₃₀ aryloxy group, a C₆-C₃₀ arylthio group, a C₁-C₃₀ heteroaryl group, a monovalent non-aromatic condensed polycyclic group, a monovalent non-aromatic condensed heteropolycyclic group, —N(Q₂₁)(Q₂₂), —S(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), —B(Q₃₆)(Q₃₇),

wherein Q₁₁ to Q₁₇, Q₂₁ to Q₂₇, and Q₃₁ to Q₃₇ may each be independently selected from a phenyl group, a pentalenyl group, an indenyl group, a naphthyl group, an azulenyl group, a heptalenyl group, an Indacenyl group, an acenaphthyl group, a fluorenyl group, a spiro-fluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an Indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyrimidinyl group, and an imidazopyridinyl group, each substituted with at least one selected from a hydrogen, a C₁-C₃₀ alkyl group, a C₂-C₃₀ alkenyl group, a C₂-C₃₀ alkynyl group, a C₁-C₃₀ alkoxy group, a cyclopentyl group, a cyclohexyl group, a cycloheptyl group, a cyclooctyl group, a cyclopentenyl group, a cyclohepcenyl group, a cycloheptenyl group, a phenyl group, a naphthyl group, an anthracenyl group, a pyrenyl group, a phenanthrenyl group, a fluorenyl group, a carbazolyl group, a benzocarbazolyl group, a dibenzocarbazolyl group, a pyridinyl group, a pyrimidinyl group, a pyrazinyl group, a pyridazinyl group, a triazinyl group, a quinolinyl group, an isoquinolinyl group, a phthalazinyl group, a quinoxalinyl group, a cinnolinyl group, and a quinazolinyl group, but embodiments are not limited thereto.

Hereinafter, an organic light-emitting display device according to an embodiment will be described in more detail with respect to Examples.

### EXAMPLES

### Example 1

An organic light-emitting display device including a pixel having a configuration as illustrated in FIG. 1 is manufactured as follows.

A TFT was formed on a glass substrate, and a polyimide resin was used to form a planarization film on the TFT. Then, silver (Ag) was patterned on the planarization film to a thickness of about 100 nm, and ITO was patterned on the Ag to a thickness of 20 nm, so as to form a first electrode. A polyimide resin was used again to form a pixel-defining layer on the first electrode. The glass substrate was ultrasonically washed with isopropyl alcohol, irradiated with UV light for 30 minutes, cleaned by exposure to ozone, and then, mounted on a vacuum depositor.

Compound HT1 was deposited on the glass substrate to form a hole injection layer (HIL), as a common layer, to a thickness of 75 nm. Compound HT2 was then deposited on the Compound HT1 to form, as common layers, a first sub-pixel HIL to a thickness of 50 nm, a second sub-pixel HIL to a thickness of 30 nm, a third sub-pixel HIL to a thickness of 20 nm, and a fourth sub-pixel HIL to a thickness of 25 nm.

CBP and RD1 were co-deposited on the HIL at a volume ratio of 99:1 to form a first sub-pixel emission layer (i.e., a red emission layer), CBP and GD1 were co-deposited on the HIL at a volume ratio of 92:8 to form a second sub-pixel emission layer (i.e., a green emission layer) to a thickness of 40 nm, BH1 and BD1 were co-deposited on the HIL at a volume ratio of 95:5 to form a third sub-pixel emission layer (i.e., a blue emission layer) to a thickness of 20 nm, and CBP and Compound 4 were co-deposited on the HIL at a volume ratio of 95:5 to form a fourth sub-pixel emission layer (i.e., a yellow emission layer).

ET1 was deposited on the emission layer to form, as a common layer, an electron transport layer (ETL) to a thickness of 10 nm. ET2 and Liq were co-deposited on the ETL at a volume ratio of 50:50 to form, as a common layer, an electron injection layer (EIL) to a thickness of 20 nm.

Mg and Ag were co-deposited on the EIL at a volume ratio of 80:20 to form a second electrode to a thickness of 12 nm, thereby completing the manufacture of the organic light-emitting display device.

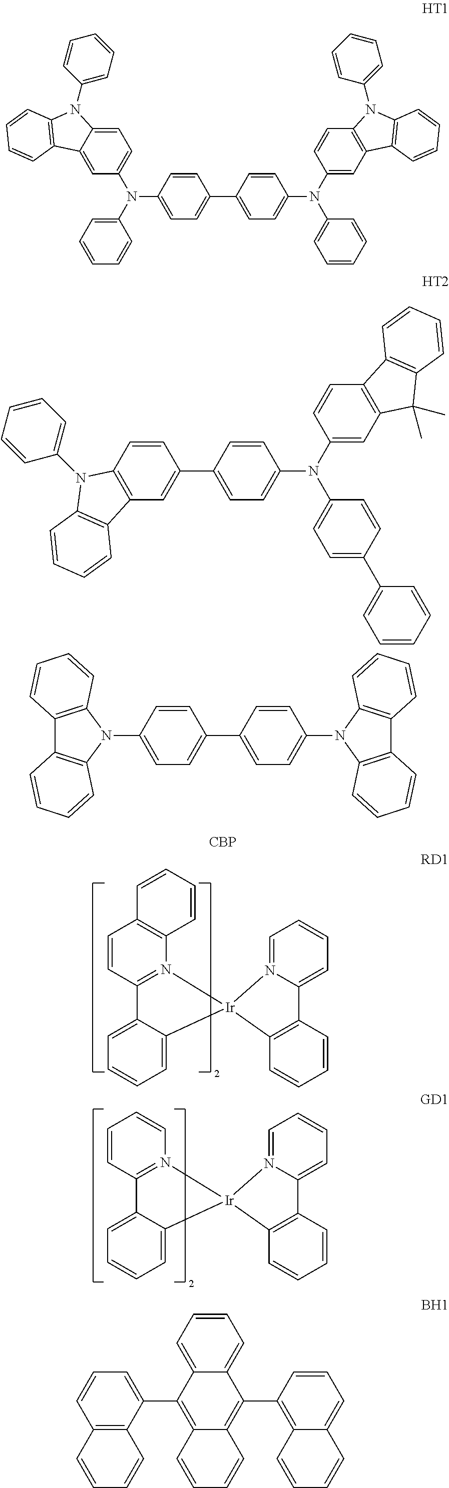

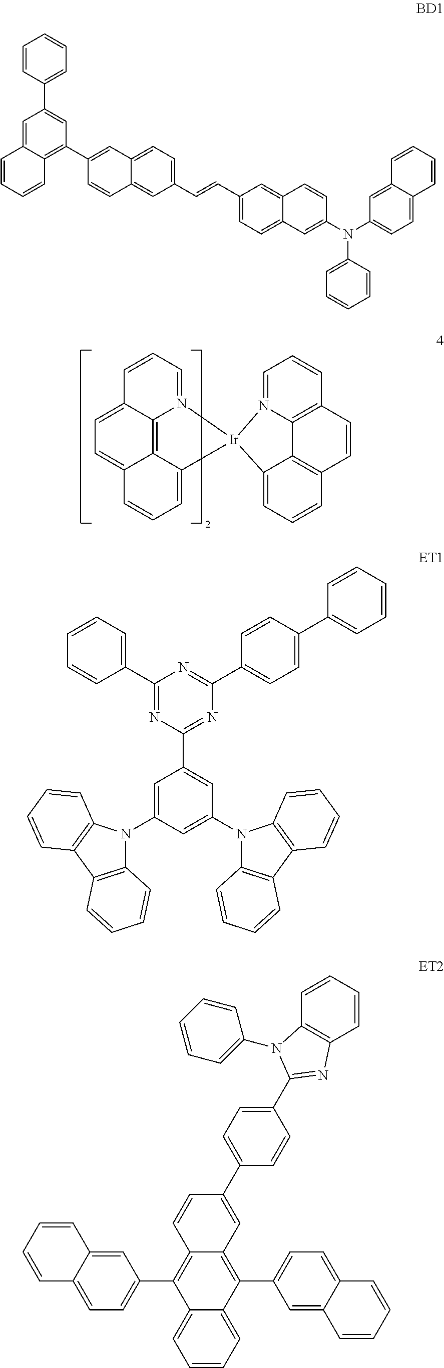

### Example 2

An organic light-emitting display device was manufactured in the same manner as in Example 1, except that Compound 5 was used instead of Compound 4.

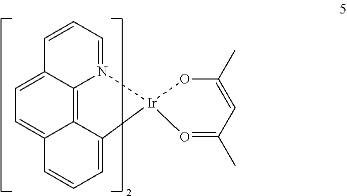

### Example 3

An organic light-emitting display device was manufactured in the same manner as in Example 1, except that Compound 10 was used instead of Compound 4.

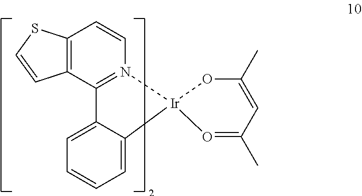

### Comparative Example 1

An organic light-emitting display device was manufactured in the same manner as in Example 1, except that the fourth sub-pixel was not formed.

### Comparative Example 2

An organic light-emitting display device was manufactured in the same manner as in Example 1, except that the fourth sub-pixel emission layer (cyan) was formed to a thickness of 25 nm by using Flrpic instead of Compound 4.

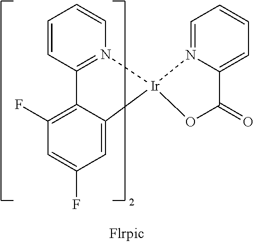

### Comparative Example 3

An organic light-emitting display device was manufactured in the same manner as in Example 1, except that the fourth sub-pixel emission layer (i.e., a yellow emission layer) was manufactured in the same manner as in Example 1 by using Compound A instead of Compound 4.

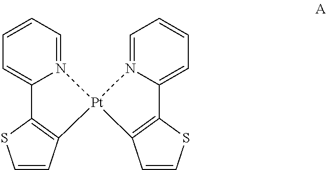

### Evaluation Example

The chromaticity coordinates and efficiencies of the organic light-emitting display devices of Examples 1 to 3 and Comparative Examples 1 to 3 were measured. In addition, the power consumption and lifespan of the organic light-emitting display devices of Examples 1 to 3 and Comparative Examples 1 to 3 were measured when white light (0.310, 0.316) at a luminance of 100 cd/m² was emitted. Consequently, the measurement results are shown in Tables 1 to 6 below (where the measurement results of the organic light-emitting display device of Example 1 are shown in Table 1, the measurement results of the organic light-emitting display device of Example 2 are shown in Table 2, the measurement results of the organic light-emitting display device of Example 3 are shown in Table 3, the measurement results of the organic light-emitting display device of Comparative Example 1 are shown in Table 4, the measurement results of the organic light-emitting display device of Comparative Example 2 are shown in Table 5, and the measurement results of the organic light-emitting display device of Comparative Example 3 are shown in Table 6). Here, the power consumption was based on an aperture ratio of 50% and a driving voltage of 10 V, and the lifespan results were obtained by measuring the time at which the brightness of the organic light-emitting display devices was 90% of the initial brightness.

TABLE 1
(Example 1)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.00 | 229 | 160 |
| Green | 0.260 | 0.658 | 32.4 | 0.17 | | |
| Blue | 0.136 | 0.108 | 2.5 | 0.14 | | |
| Yellow | 0.460 | 0.432 | 29.1 | 0.69 | | |

TABLE 2
(Example 2)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.00 | 228 | 180 |
| Green | 0.260 | 0.658 | 32.4 | 0.15 | | |
| Blue | 0.136 | 0.108 | 2.5 | 0.14 | | |
| Yellow | 0.459 | 0.436 | 30.2 | 0.70 | | |

TABLE 3
(Example 3)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.00 | 212 | 190 |
| Green | 0.260 | 0.658 | 32.4 | 0.05 | | |
| Blue | 0.136 | 0.108 | 2.5 | 0.17 | | |
| Yellow | 0.491 | 0.513 | 78.2 | 0.78 | | |

TABLE 4
(Comparative Example 1)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.30 | 254 | 120 |
| Green | 0.260 | 0.658 | 32.4 | 0.54 | | |
| Blue | 0.136 | 0.108 | 2.5 | 0.16 | | |

TABLE 5
(Comparative Example 2)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.37 | 136 | 5 |
| Green | 0.260 | 0.658 | 32.4 | 0.17 | | |
| Blue | 0.136 | 0.108 | 2.5 | 0.00 | | |
| Cyan | 0.123 | 0.250 | 16.5 | 0.46 | | |

TABLE 6
(Comparative Example 3)

| | Chromaticity | | Effi- | 100 nit, NTSC (0.310, 0.316) | | |
|---|---|---|---|---|---|---|
| Sub- | coordinates | | ciency | Luminance | Current | Lifespan |
| pixel | CIE_x | CIE_y | (cd/A) | ratio | (mW) | (h) |
| Red | 0.650 | 0.348 | 21.2 | 0.00 | 324 | 130 |
| Green | 0.260 | 0.658 | 32.4 | −0.62 | | |
| Blue | 0.136 | 0.108 | 2.5 | 0.15 | | |
| Yellow | 0.392 | 0.560 | 19.4 | 1.46 | | |

Referring to Tables 1 to 6, it was confirmed that the organic light-emitting display devices of Examples 1 to 3 had low power consumption and improved lifespan properties, as compared with those of the organic light-emitting display devices of Comparative Examples 1 to 3. In addition, the organic light-emitting display devices of Examples 1 to 3 had excellent color reproducibility, as compared with that of the organic light-emitting display device of Comparative Example 1, based on the fact that the organic light-emitting display devices of Examples 1 to 3 had high-resolution of the NTSC color gamut.

As described above, according to one or more of the above exemplary embodiments, an organic light-emitting display device shows high color purity, low power consumption, and long lifespan characteristics.

It should be understood that exemplary embodiments described herein should be considered in a descriptive sense only and not for purposes of limitation. Descriptions of features or aspects within each exemplary embodiment should typically be considered as being available for other similar features or aspects in other exemplary embodiments.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While one or more exemplary embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. An organic light-emitting display device comprising:
a pixel comprising a first sub-pixel, a second sub-pixel, a third sub-pixel, and a fourth sub-pixel,
wherein the first sub-pixel comprises a first emission layer that emits a first color light, the second sub-pixel comprises a second emission layer that emits a second color light, the third sub-pixel comprises a third emission layer that emits a third color light, and the fourth sub-pixel comprises a fourth emission layer that emits a fourth color light;
the first color light, the second color light, the third color light, and the fourth color light are different from each other;
at least one emission layer selected from the first emission layer, the second emission layer, the third emission layer, and the fourth emission layer comprises an organometallic compound; and
the organometallic compound comprises iridium (Ir).

2. The organic light-emitting display device of claim 1, wherein a maximum emission wavelength of the organometallic compound is in a range of about 540 nm to about 620 nm.

3. The organic light-emitting display device of claim 1, wherein the organometallic compound is represented by Formula 1:
Formula 1 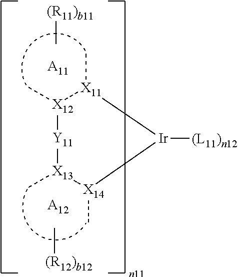
wherein X₁₁ to X₁₄ are each independently selected from a nitrogen atom and a carbon atom;
A₁₁ and A₁₂ are each independently selected from a C₅-C₆₀ cyclic group and a C₁-C₆₀ heterocyclic group;
Y₁₁ is selected from a single bond and a divalent linking group;
R₁₁ and R₁₂ are each independently selected from a hydrogen, a deuterium, —F, —Cl, —Br, —I, a substituted or unsubstituted C₁-C₆₀ alkyl group, a substituted or unsubstituted C₆-C₆₀ aryl group, and a substituted or unsubstituted C₁-C₆₀ heteroaryl group;
R₁₁ and R₁₂ are optionally fused to each other to form a saturated or unsaturated ring;
b11 and b12 are each independently selected from 1, 2, 3, and 4;
n11 is selected from 1, 2, and 3;
L₁₁ is selected from a monovalent organic ligand, a divalent organic ligand, a trivalent organic ligand, and a tetravalent organic ligand; and
n12 is selected from 1, 2, 3, and 4.

4. The organic light-emitting display device of claim 1, wherein the organometallic compound comprises a phosphorescent dopant.

5. The organic light-emitting display device of claim 3, wherein, in Formula 1, X₁₁ is a nitrogen atom and X₁₂ to X₁₄ are each independently a carbon atom.

6. The organic light-emitting display device of claim 3, wherein, in Formula 1, A₁₁ and A₁₂ are each independently selected from a benzene, a naphthalene, a fluorene, an indene, a pyrrole, a thiophene, a furan, an imidazole, a pyrazole, a thiazole, an isothiazole, an oxazole, an isoxazole, a triazole, a pyridine, a pyrazine, a pyrimidine, a pyridazine, a triazine, a quinoline, an isoquinoline, a quinoxaline, a quinazoline, an indole, a benzimidazole, a benzothiazole, a benzoxazole, a thienopyridine, a benzofuran, a benzothiophene, a dibenzofuran, and a dibenzothiophene.

7. The organic light-emitting display device of claim 3, wherein, in Formula 1, A₁₁ and A₁₂ are each independently selected from a benzene, a naphthalene, a pyridine, a pyrazine, a quinoline, an isoquinoline, a benzothiazole, a benzoxazole, and a thienopyridine.

8. The organic light-emitting display device of claim 3, wherein, in Formula 1, Y₁₁ is a single bond.

9. The organic light-emitting display device of claim 3, wherein, in Formula 1, R₁₁ and R₁₂ are each independently selected from a hydrogen, a methyl group, an ethyl group, and a phenyl group.

10. The organic light-emitting display device of claim 3, wherein, in Formula 1, R₁₁ and R₁₂ are connected to each other via Y₁₂,
Y₁₂ is selected from a single bond, *—O—*′, *—S—*′, *—N(Z₁₁)—*′, *—[C(Z₁₁)(Z₁₂)]ₘ₁₁—*′, a group represented by Formula 10-1, and a group represented by Formula 10-2: 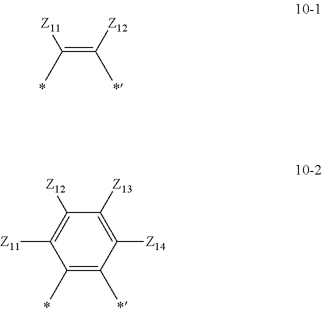
wherein Z₁₁ to Z₁₄ are each independently selected from a hydrogen, a deuterium, —F, —Cl, —Br, —I, a substituted or unsubstituted C₁-C₆₀ alkyl group, and a substituted or unsubstituted C₆-C₆₀ aryl group,
m11 is selected from 1, 2, 3, and 4, and
* and *′ each indicate a binding site to a neighboring atom.

11. The organic light-emitting display device of claim 3, wherein, in Formula 1, n11 is selected from 2 and 3.

12. The organic light-emitting display device of claim 3, wherein the organometallic compound is represented by one of Formulae 1-1 and 1-2: 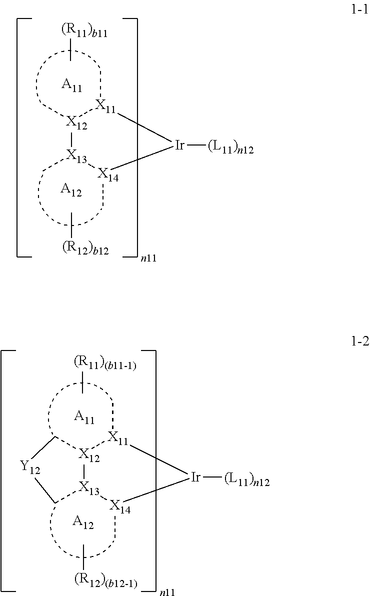
wherein X₁₁ to X₁₄, A₁₁, A₁₂, Z₁₁, Z₁₂, R₁₁, R₁₂, b11, b12, n11, L₁₁, and n12 are defined the same as those provided in connection with Formula 1,
Y₁₂ is selected from a single bond, *—O—*′, *—S—*′, *—N(Z₁₁)—*′, *—[C(Z₁₁)(Z₁₂)]ₘ₁₁—*′, a group represented by Formula 10-1, and a group represented by Formula 10-2: 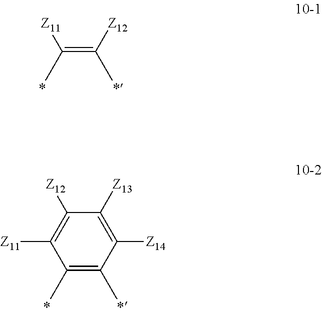
wherein Z₁₁ to Z₁₄ are each independently selected from a hydrogen, a deuterium, —F, —Cl, —Br, —I, a substituted or unsubstituted C₁-C₆₀ alkyl group, and a substituted or unsubstituted C₆-C₆₀ aryl group,
m11 is selected from 1, 2, 3, and 4, and
* and *′ each indicate a binding site to a neighboring atom.

13. The organic light-emitting display device of claim 1, wherein the organometallic compound is at least one selected from Compounds 1 to 12:

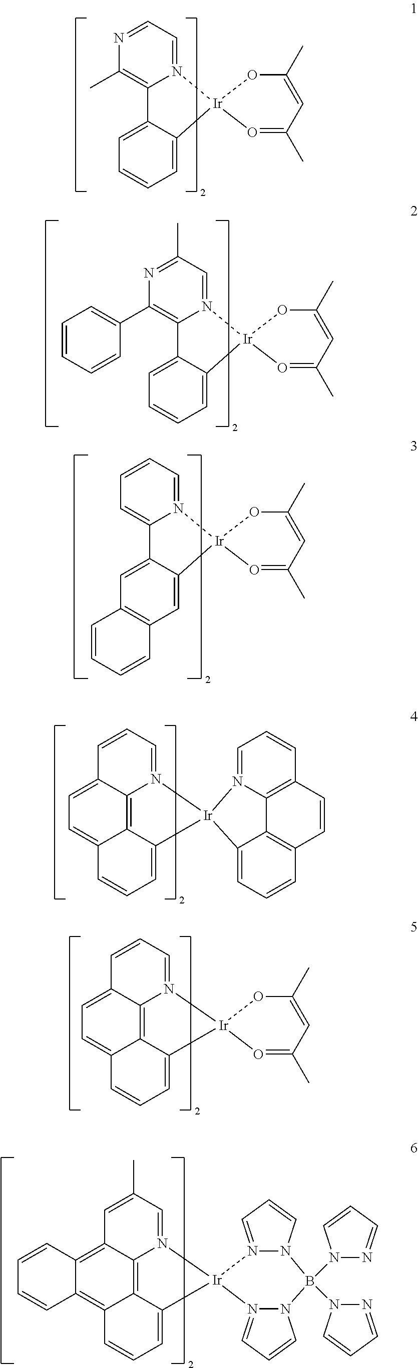

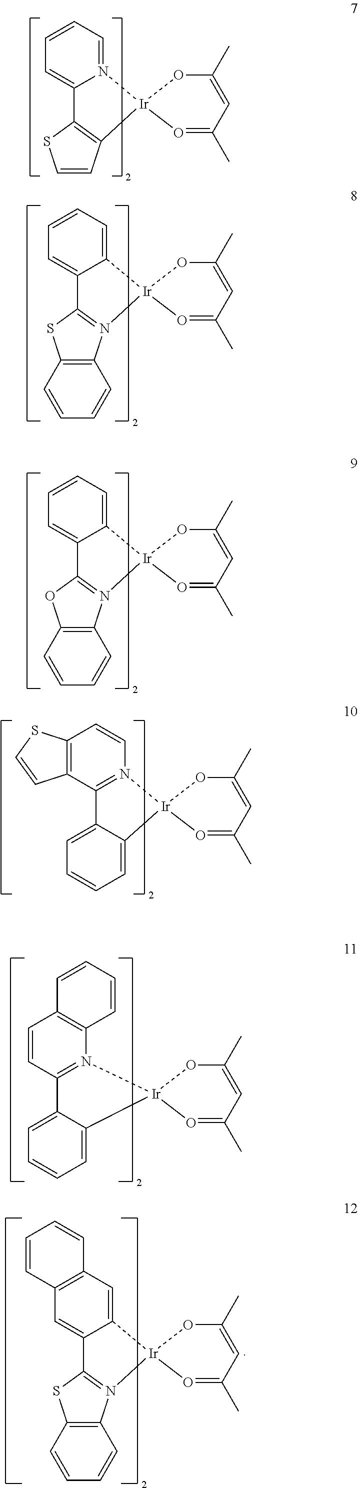

14. The organic light-emitting display device of claim 1, wherein the first color light, the second color light, the third color light, and the fourth color light are combined with each other to emit white light.

15. The organic light-emitting display device of claim 1, wherein only one emission layer selected from the first emission layer, the second emission layer, the third emission layer, and the fourth emission layer comprises the organometallic compound.

16. The organic light-emitting display device of claim 1, wherein the first color light is red color light, the second color light is green color light, the third color light is blue color light, and the fourth color light is yellow color light.

17. The organic light-emitting display device of claim 1, wherein at least one selected from the first sub-pixel, the second sub-pixel, the third sub-pixel, and the fourth sub-pixel has an external quantum efficiency that is greater than 20% to 100%.

18. The organic light-emitting display device of claim 1, wherein the first sub-pixel, the second sub-pixel, the third sub-pixel, and the fourth sub-pixel each have an area that is identical to or different from each other.

19. The organic light-emitting display device of claim 1, wherein the pixel further comprises a fifth sub-pixel,
wherein the fifth sub-pixel comprises a fifth emission layer that emits a fifth color light, and
the fifth color light is identical to or different from one selected from the first color light, the second color light, and third color light, and the fourth color light.

20. The organic light-emitting display device of claim 1, wherein the first sub-pixel, the second sub-pixel, the third sub-pixel, and the fourth sub-pixel are disposed in a stripe type, a rectangular type, or a pentile type.
